(19) United States
(12) Patent Application Publication
(10) Pub. No.: US 2026/0117419 A1
(43) Pub. Date: Apr. 30, 2026

(54) GALLIUM NITRIDE SINGLE-CRYSTAL SUBSTRATE AND METHOD OF PRODUCING SAME

(71) Applicant: SUMITOMO CHEMICAL COMPANY, LIMITED, Tokyo (JP)

(72) Inventors: Tetsuji FUJIMOTO, Hitachi-shi (JP); Nobuyuki YOSHIDA, Niihama-shi (JP); Takayuki SUZUKI, Hitachi-shi (JP); Masatomo SHIBATA, Hitachi-shi (JP)

(73) Assignee: SUMITOMO CHEMICAL COMPANY, LIMITED, Tokyo (JP)

(21) Appl. No.: 19/368,957

(22) Filed: Oct. 24, 2025

(30) Foreign Application Priority Data
Oct. 25, 2024 (JP) 2024-188115

(51) Int. Cl. C30B 29/40; C30B 25/18

(52) U.S. Cl. CPC C30B 29/406; C30B 25/18

(57) ABSTRACT

Provided is a technique of producing a gallium nitride single-crystal substrate in which a stress at an edge is reduced, the gallium nitride single-crystal substrate including a single crystal of gallium nitride, the substrate being a circular substrate having concentric striations observed as bright and dark stripes when a principal surface of the substrate is observed with a fluorescence microscope, in which a substrate center, which is a center of the circular substrate, is located at a position displaced from a striation center, which is a center of the concentric striations.

### TECHNICAL FIELD

The present disclosure relates to a gallium nitride single-crystal substrate and a method of producing same.

### BACKGROUND OF THE INVENTION

As a technique of producing a single-crystal substrate of gallium nitride (GaN), a method of obtaining the substrate by growing a gallium nitride single-crystal member which is larger than the substrate and which serves as a base material, and removing an outer periphery of the base material has been employed (for example, see Japanese Patent Laid-Open Publication No. 2013-60349).

In a plane of a gallium nitride single-crystal substrate, stress has a distribution. When handling a gallium nitride single-crystal substrate, for example, during processing to form a cutout such as an orientation flat, a large amount of stress at an edge of the substrate tends to cause a defect such as cracking at the edge.

### RELATED APPLICATION

Patent Document 1: Japanese Patent Laid-Open Publication No. 2013-60349

### SUMMARY OF THE INVENTION

An object of the present disclosure is to provide a technique of producing a gallium nitride single-crystal substrate in which a stress at an edge is reduced.

According to one aspect of the present disclosure, provided is a gallium nitride single-crystal substrate including a single crystal of gallium nitride, the substrate being a circular substrate having concentric striations observed as bright and dark stripes when a principal surface of the substrate is observed with a fluorescence microscope, in which
a substrate center is located at a position displaced from a striation center, the substrate center being a center of the circular substrate, and the striation center being a center of the concentric striations.

According to another aspect of the present disclosure, provided is a method of producing a gallium nitride single-crystal substrate, the method including:
forming a base material by growing a gallium nitride single crystal on a circular seed substrate while causing at least self-rotation of the seed substrate, in which the seed substrate has a diameter larger than the diameter of a circular gallium nitride single-crystal substrate to be obtained; and
obtaining the gallium nitride single-crystal substrate by processing the base material in such a manner that a substrate center is located at a position different from a center of the self-rotation during growth of the gallium nitride single crystal, in which the substrate center is a center of the circular gallium nitride single-crystal substrate.

A technique of producing a gallium nitride single-crystal substrate in which a stress at an edge is reduced is provided.

### BRIEF DESCRIPTION OF DRAWINGS

FIG. 1 is a schematic plan view illustrating a substrate 10 according to a first embodiment of the present disclosure;

FIG. 2 is a graph showing a distribution in a displacing direction of equivalent stress of each of a base material 100 and the substrate 10 in the first embodiment;

FIG. 3 is a graph showing a distribution in the displacing direction of equivalent stress of each of the substrate 10 of a first comparative embodiment and the substrate 10 of the first embodiment;

FIG. 4 is a graph showing how the equivalent stress at an edge of the substrate 10 changes depending on a displacement amount d;

FIG. 5 is a schematic plan view illustrating a first example of the substrate 10 according to a second embodiment;

FIG. 6 is a graph showing a distribution in the displacing direction of equivalent stress of each of the substrate 10 with no cutout 20 formed according to the first embodiment and the substrate 10 with a cutout 20 formed on a substrate center C1 side according to the first example of the second embodiment;

FIG. 7 is a graph showing a distribution in the displacing direction of equivalent stress of each of the substrate 10 with the cutout 20 formed according to a second comparative embodiment and the substrate 10 with the cutout 20 formed on the substrate center C1 side according to the first example of the second embodiment;

FIG. 8A is a schematic plan view illustrating an in-plane distribution of equivalent stress of the substrate 10 with the cutout 20 formed on the substrate center C1 side in the first example of the second embodiment;

FIG. 8B is a schematic plan view illustrating an in-plane distribution of equivalent stress of the substrate 10 with the cutout 20 formed according to the second comparative embodiment;

FIG. 9 is a schematic plan view illustrating a second example of the substrate 10 according to the second embodiment;

FIG. 10 is a graph showing a distribution in the displacing direction of equivalent stress of each of the substrate 10 with no cutout 20 formed according to the first embodiment and the substrate 10 with the cutout 20 formed on a striation center C0 side in the second example of the second embodiment;

FIG. 11 is a schematic plan view illustrating a distribution of a deflection amount in the substrate 10 having an eccentric configuration;

FIG. 12 is a schematic plan view illustrating the substrate 10 according to the first comparative embodiment;

FIG. 13 is a graph showing a distribution in the displacing direction of equivalent stress of each of the base material 100 and the substrate 10 in the first comparative embodiment;

FIG. 14 is a schematic plan view illustrating the substrate 10 according to the second comparative embodiment;

FIG. 15 is a graph showing a distribution in the displacing direction of equivalent stress of each of the substrate 10 with no cutout 20 formed according to the first comparative embodiment and the substrate 10 with the cutout 20 formed according to the second comparative embodiment;

FIG. 16A is a schematic cross-sectional view schematically illustrating a method of producing the base material 100 and the substrate 10;

FIG. 16B is a schematic cross-sectional view schematically illustrating the method of producing the base material 100 and the substrate 10;

FIG. 16C is a schematic cross-sectional view schematically illustrating the method of producing the base material 100 and the substrate 10;

FIG. 17 is a fluorescence micrograph showing an example of striations 30;

FIG. 18A is a schematic plan view illustrating a GaN substrate in an experiment in which an orientation flat is formed on the GaN substrate with a displacement amount d changed, and likelihood of occurrence of cracking is investigated; and

FIG. 18B is a table summarizing results of the experiment of FIG. 18A.

### DETAILED DESCRIPTION

### First Embodiment

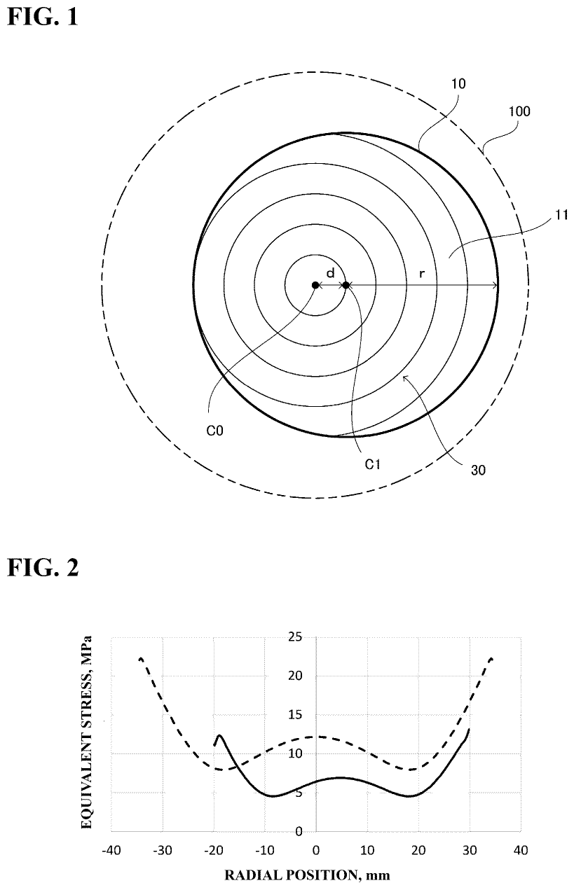

A gallium nitride single-crystal substrate 10 (hereinafter, also simply referred to as a substrate 10) according to a first embodiment of the present disclosure is described. FIG. 1 is a schematic plan view illustrating the substrate 10 according to the first embodiment. The substrate 10 is a member obtained by being cut from a base material 100. An outline of the base material 100 is indicated by a dashed double-dotted line, and an outline of the substrate 10 is indicated by a solid line. Note that the outline of the substrate 10 is indicated by a bold solid line for ease of illustration.

The substrate 10 is a circular substrate including a single crystal of gallium nitride and having concentric striations 30 observed as bright and dark stripes when a principal surface 11 of the substrate 10 is observed with a fluorescence microscope. The principal surface 11 of the substrate 10 is a c-plane.

The base material 100 includes a single crystal of gallium nitride and has a circular shape. As described later with respect to a method of producing the base material 100 and the substrate 10, a center C0 (hereinafter, also referred to as a striation center C0) of concentric circles of the striations 30 is located at a center of the circular base material 100.

The substrate 10 has a radius r. The radius r of the substrate 10 is, for example, 25 mm or more (diameter 2r is, for example 50 mm or more). The substrate 10 according to the present embodiment has the feature in which a center C1 (hereinafter, also referred to as a substrate center C1) of the circular substrate 10 is located at a position displaced from the striation center C0. A distance between the substrate center C1 and the striation center C0 is referred to as a displacement amount d. A direction from the striation center C0 toward the substrate center C1 is referred to as a displacing direction. The configuration in which the substrate center C1 is displaced from the striation center C0 according to the embodiment is also referred to as an eccentric configuration.

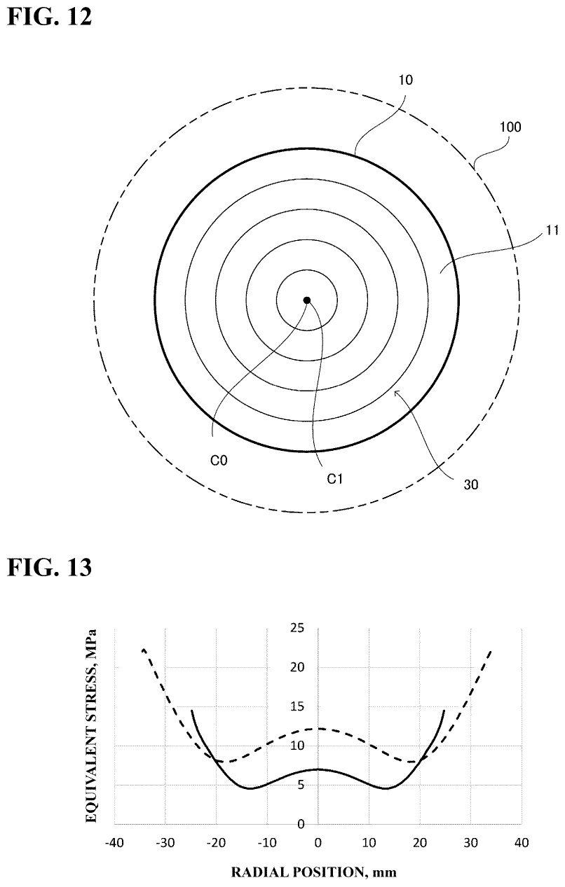

FIG. 12 is a schematic plan view illustrating the substrate 10 according to a first comparative embodiment corresponding to related art. In the first comparative embodiment, the substrate 10 is obtained by cutting the base material 100 so that the striation center C0 and the substrate center C1 coincide. The configuration in which the substrate center C1 and the striation center C0 coincide according to the comparative embodiment is also referred to as a concentric configuration.

The inventor of the present application investigates, through simulation, a difference between a stress distribution in the substrate 10 having the concentric configuration and a stress distribution in the substrate 10 having the eccentric configuration. The method and conditions of the simulation are as follows. As a numerical calculation method, a steady-state thermal conduction structure interaction analysis based on the finite element method is employed. Ansys is used as analysis software. A full model of the substrate is used as an analysis model. The elastic modulus, thermal conductivity, and linear coefficient of expansion of gallium nitride are set as material physical properties. As analysis conditions, the analysis model is divided into four (at 90° intervals), out-of-plane deformation is constrained with respect to a cut surface, and the center is fixed. A concentric temperature distribution is applied to the front surface of the substrate, and a uniform temperature is applied to the rear surface. The temperature conditions are fitted with an amount of warpage that occurs in the actual substrate.

The radius r of the substrate 10 is set to 25 mm (diameter 2r is 50 mm). The radius of the base material 100 is set to 35 mm (diameter is 70 mm). Note that the radius of the base material 100 is not particularly limited as long as the substrate 10 can be obtained from the base material 100.

The concentric configuration is considered as a case in which the displacement amount d is 0, and the eccentric configuration is considered as a case in which the displacement amount d is not 0, and both configurations are described together. The center C1 of the substrate 10 is set at a position separated from the center C0 of the base material 100 by the displacement amount d. The displacement amount d is changed to 0 mm, 2.5 mm, 5 mm, and 9 mm, and an in-plane stress distribution of the substrate 10 at each displacement amount d is calculated. A deflection amount distribution is also calculated.

Note that in the concentric configuration, the striation center C0 and the substrate center C1 coincide, and no displacing direction is defined unlike the eccentric configuration. In this simulation, the displacing direction set in the eccentric configuration is referred to as the displacing direction also in the concentric configuration for convenience.

FIG. 2 is a graph showing the distribution in the displacing direction of equivalent stress of each of the base material 100 and the substrate 10 in the eccentric configuration (the first embodiment). A result in a case in which the displacement amount d is 5 mm is shown. The stress distribution of the base material 100 is indicated by a dashed line, and the stress distribution of the substrate 10 is indicated by a solid line.

A radial position of 0 mm indicates the center C0 of the base material 100. The side on which the center C1 of the substrate 10 is located with respect to the center C0 of the base material 100 is defined as the positive side of the displacing direction. A radial position of +5 mm indicates the center C1 of the substrate 10. The base material 100 corresponds to a radial position range from −35 mm to +35 mm, and the substrate 10 corresponds to a radial position range from −20 mm to +30 mm.

The stress distribution of the base material 100 and the stress distribution of the substrate 10 have substantially a similar shape. Common features of the two are as follows. Note that when describing the common features of the stress distribution of the base material 100 and the stress distribution of the substrate 10, both the base material 100 and the substrate 10 may sometimes be collectively referred to as the substrate. A local maximum of the equivalent stress exists at a central portion of the substrate. The equivalent stress decreases toward the edge side, reaches a local minimum at an intermediate radial position, then increases toward the edge side, and is maximized at an edge of the substrate.

A difference between the stress distribution of the base material 100 and the stress distribution of the substrate 10 is as follows. As compared with the base material 100, the substrate 10 cut out from the base material 100 has a smaller magnitude of stress (absolute value of stress).

Incidentally, the base material 100 can also be regarded as a substrate with a larger radius, and the substrate 10 can also be regarded as a substrate with a smaller radius. From the comparison between the stress distribution of the base material 100 and the stress distribution of the substrate 10, it is found the stress at the edge of the substrate tends to increase as the radius of the substrate increases.

FIG. 13 is a graph showing the distribution in the displacing direction of the equivalent stress of each of the base material 100 and the substrate 10 in the concentric configuration (the first comparative embodiment). The stress distribution of the base material 100 is indicated by a dashed line, and the stress distribution of the substrate 10 is indicated by a solid line.

The stress distribution of the base material 100 is similar to that in the eccentric configuration. In the concentric configuration, a radial position of 0 mm indicates the center C1 of the substrate 10, and the substrate 10 corresponds to a radial position range from −25 mm to +25 mm. Also in the concentric configuration, common features and a difference between the stress distribution of the base material 100 and the stress distribution of the substrate 10 are similar to those described for the eccentric configuration.

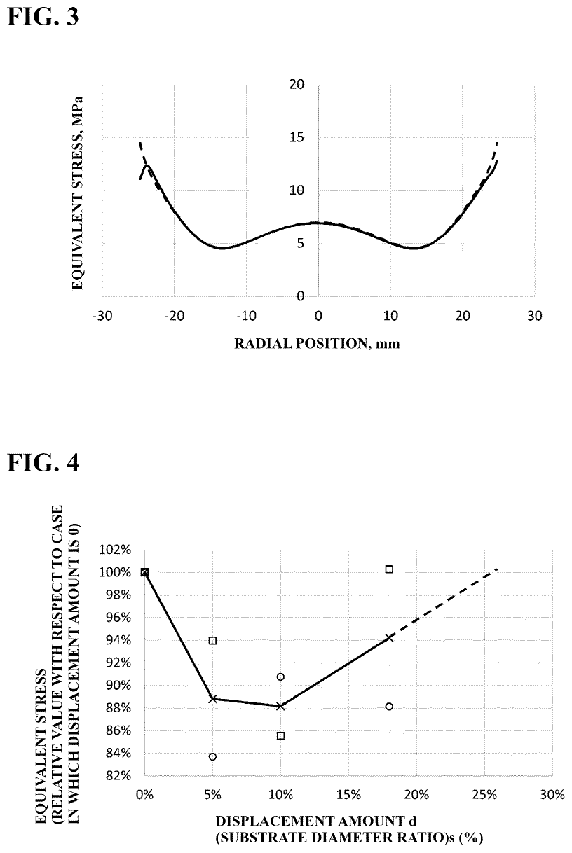

FIG. 3 is a graph showing a distribution in the displacing direction of the equivalent stress (FIG. 13) of the substrate 10 in the concentric configuration (the first comparative embodiment) and the equivalent stress (FIG. 2) of the substrate 10 in the eccentric configuration (the first embodiment). The curves of the concentric and eccentric configurations are superimposed in the graph, with the center C1 of the substrate 10 set as a radial position of 0 mm in both configurations. The stress distribution in the concentric configuration is indicated by a dashed line, and the stress distribution in the eccentric configuration is indicated by a solid line.

As compared with the stress distribution in the concentric configuration, the stress distribution in the eccentric configuration exhibits a decrease in stress at each edge (specifically, a region with a width of about 2 to 3 mm from an end) in the displacing direction. In a region closer to the center than the edges, where a decrease in stress is not particularly observed, the stress distribution in the eccentric configuration substantially coincides with the stress distribution in the concentric configuration.

The stress distribution in the concentric configuration is symmetrical with respect to the center C1 of the substrate 10. That is, stress values at the edges of the substrate 10 on both sides in the displacing direction are equal. On the other hand, in the stress distribution in the eccentric configuration, an asymmetry arises in which the stress values at the edges (the edge on the striation center C0 side and the edge on the substrate center C1 side) are slightly different from each other.

Note that the decrease in stress at the edges in the eccentric mode is observed not only at the edges on both sides in the displacing direction. In the eccentric configuration, the tendency of stress to decrease at edges is observed throughout the entire circumferential direction of the substrate 10.

As described above, in the eccentric configuration according to the present embodiment, that is, when the substrate 10 is obtained from the base material 100 with the substrate center C1 displaced from the striation center C0, the stress at the edges of the substrate 10 can be reduced as compared with the concentric configuration according to the comparative embodiment. Consequently, when handling the substrate 10, for example, when performing processing of forming a cutout 20 such as an orientation flat as in a second embodiment described later, for example, cracking at edges of the substrate 10 can be suppressed.

As described above, as the radius r of the substrate 10 increases, the stress at edges of the substrate 10 tends to increase. Therefore, the effect of reducing stress at the edges provided in the present embodiment is preferably provided as the radius r of the substrate 10 increases.

FIG. 4 is a graph showing the change in equivalent stress at edges of the substrate 10 depending on the displacement amount d. The horizontal axis represents the displacement amount d, and the vertical axis represents the equivalent stress. Values on the horizontal axis and the vertical axis are represented by relative values as described below. In the following description, the relative values may sometimes be shown in parentheses.

With respect to the displacing direction, the equivalent stress at the edge on the striation center C0 side (the left side in FIG. 1) is indicated by square plots, and the equivalent stress at the edge on the substrate center C1 side (the right side in FIG. 1) is indicated by circle plots. The average equivalent stress of that at the edge on the striation center C0 side and that at the edge on the substrate center C1 side is indicated by cross plots.

Hereinafter, the equivalent stress at the edge on the striation center C0 side is also referred to as C0-side stress, the equivalent stress at the edge on the substrate center C1 side is also referred to as C1-side stress, and the average equivalent stress of the C0-side stress and the C1-side stress is also referred as average stress.

The horizontal axis represents the displacement amount d as a ratio to the diameter 2r of the substrate 10 taken as 100%. In the present example, the diameter 2r of the substrate 10 is 50 mm, and the displacement amounts d of plotted samples are 0 mm (0%), 2.5 mm (5%), 5 mm (10%), and 9 mm (18%).

The vertical axis represents the equivalent stress as a ratio to the equivalent stress at a displacement amount d of 0 mm, which is taken as 100%. Specifically, the equivalent stress is represented as a ratio to the average stress at a displacement amount d of 0 mm, which is taken as 100%.

As the equivalent stress at an edge, the maximum value of equivalent stress in the vicinity of the edge is used. For example, at a displacement amount of 5 mm (10%), the equivalent stress at each edge is evaluated as follows. As illustrated in FIG. 3, the distribution of the C0-side stress has a local maximum. Accordingly, an equivalent stress value at the local maximum is taken as the C0-side stress (rather than a smaller value obtained at an end on the edge side beyond the local maximum). On the other hand, in the distribution of the C1-side stress, the equivalent stress increases up to the end of the edge (without a local maximum). Accordingly, the equivalent stress at the end of the edge is taken as the C1-side stress.

Note that the local maximum in the distribution of the equivalent stress at an edge may or may not appear depending on the displacement amount d. In addition, whether the local maximum appears at the edge on the striation center C0 side or at the edge on the substrate center C1 side may vary depending on the displacement amount d. In addition, whether the C0-side stress or the C1-side stress is larger may vary depending on the displacement amount d. Although the reason for occurrence of such a phenomenon is not clear, this phenomenon is a finding newly obtained through the present simulation.

At a displacement amount of 2.5 mm (5%), the C0-side stress has no local maximum and represents the value at the end of the edge, and the C1-side stress has a local maximum and represents the value at the local maximum. At a displacement amount of 5 mm (10%), the C0-side stress has a local maximum and represents the value at the local maximum as described above, and the C1-side stress has no local maximum and represents the value at the end of the edge. At a displacement amount of 9 mm (18%), the C0-side stress and the C1-side stress both have no local maximum and each represent the value at the end of the edge.

In the concentric configuration, that is, at a displacement amount d of 0 mm (0%), the C0-side stress is 14.5 MPa (100%), the C1-side stress is 14.5 MPa (100%), and the average stress is 14.5 MPa (100%).

Results in the eccentric configuration are as follows. At a displacement amount d of 2.5 mm (5%), the C0-side stress is 13.6 MPa (93.9%), the C1-side stress is 12.1 MPa (83.7%), and the average stress is 12.8 MPa (88.8%). At a displacement amount d of 5 mm (10%), the C0-side stress is 12.4 MPa (85.5%), the C1-side stress is 13.1 MPa (90.8%), and the average stress is 12.7 MPa (88.1%). At a displacement amount d of 9 mm (18%), the C0-side stress is 14.5 MPa (100%), the C1-side stress is 12.7 MPa (88.1%), and the average stress is 13.6 MPa (94.2%).

Each of the C0-side stress, the C1-side stress, and the average stress substantially exhibits a tendency to decrease as the displacement amount d increases from 0 to a certain level, and to increase as the displacement amount d increases further beyond the certain level.

In consideration of the average stress as a representative example, the following tendency is found. The average stress is 100% at a displacement amount d of 0%, decreases to below about 90% at a displacement amount d of about 5% to 10%, then turns into an increase, and reaches about 100% at a displacement amount d of about 26%. From the viewpoint of reducing the average stress by employing the eccentric configuration as compared with the case of the concentric configuration, a displacement amount d range in which the average stress is less than 100% is preferably used.

An indication of the lower limit of the displacement amount d is as follows. In order to make the average stress less than 100%, 98% or less, 96% or less, 94% or less, 92% or less, and 90% or less, the displacement amount d is preferably set to more than 0%, 0.9% or more, 1.8% or more, 2.7% or more, 3.6% or more, and 4.5% or more, respectively.

Note that when the displacement amount d is set to more than 0%, the average stress can be reduced to less than 100%. However, from the viewpoint of clearly displacing the substrate center C1 from the striation center C0 to reduce the average stress, the displacement amount d is preferably set to 0.5% or more so that the average stress is less than 99%.

An indication of the upper limit of the displacement amount d is as follows. In order to make the average stress less than 100%, 98% or less, 96% or less, 94% or less, 92% or less, and 90% or less, the displacement amount d is preferably set to less than 25.7%, 23.0% or less, 20.4% or less, 17.8% or less, 15.1% or less, and 12.5% or less, respectively.

From the viewpoint of investigating a more preferable condition, when the C0-side stress and the C1-side stress are further studied, the following tendency is found. In the concentric configuration in which the displacement amount d is 0, the C0-side stress and the C1-side stress coincide, and the average stress is also the same accordingly. On the other hand, in the eccentric configuration in which the displacement amount d is not 0, a deviation (asymmetry) between the C0-side stress and the C1-side stress is observed.

In a sample with a displacement amount d of 5% and a sample with a displacement amount d of 18%, the C0-side stress is larger than the C1-side stress. In a sample with a displacement amount d of 10%, the C1-side stress is larger than the C0-side stress. In addition, the deviation between the C0-side stress and the C1-side stress is larger in the sample with a displacement amount d of 5% and the sample with a displacement amount d of 18% than in the sample with a displacement amount d of 10%.

When comparing the samples with displacement amounts d of 5%, 10%, and 18% with one another, the average stress is the smallest, and the deviation between the C0-side stress and the C1-side stress is also the smallest in the sample with a displacement amount d of 10%. From such a viewpoint, as an indication of the displacement amount d, the displacement amount d is preferably set to around 10%, for example, 5% or more and 15% or less.

Note that in the sample with a displacement amount d of 18%, although the C1-side stress and the average stress are sufficiently small, the C0-side stress reaches 100%. From such a viewpoint, it can be said that the displacement amount d is more preferably 18% or less.

### Second Embodiment

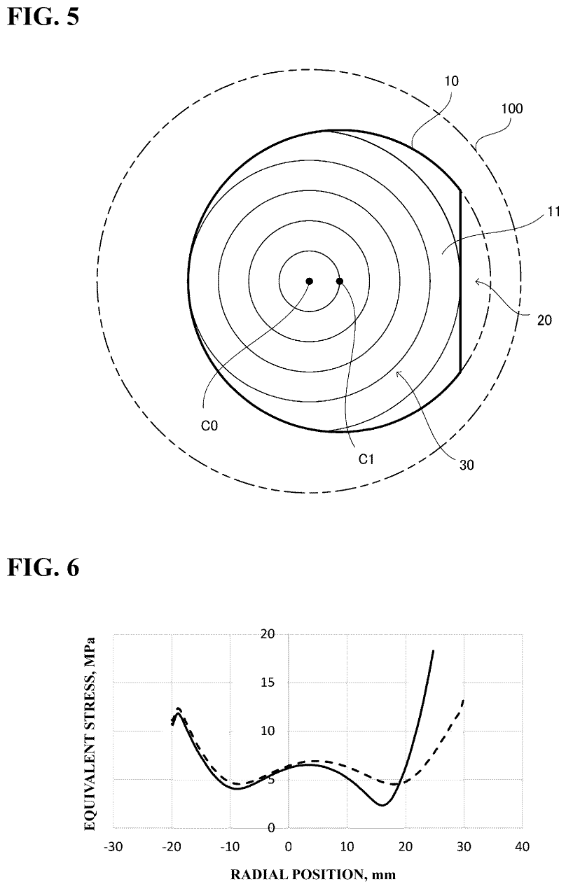

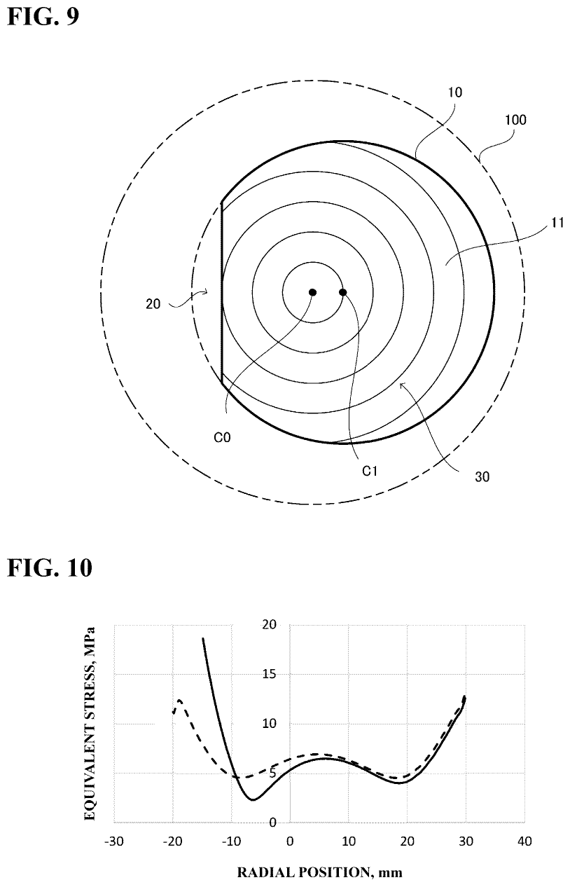

Next, the substrate 10 according to a second embodiment is described. FIG. 5 is a schematic plan view illustrating a first example of the substrate 10 according to the second embodiment, and FIG. 9 is a schematic plan view illustrating a second example of the substrate 10 according to the second embodiment. The substrate 10 according to the second embodiment is a substrate obtained by forming, on an edge of the substrate 10 according to the first embodiment (that is, according to the eccentric configuration), a cutout 20 that indicates the crystal orientation of the gallium nitride single crystal forming the substrate 10. The cutout 20 is, for example, an orientation flat or a notch.

The substrate 10 according to the second embodiment also has a circular shape. The term “circular” herein includes not only a configuration in which the substrate has no cutout 20 on the edge of the substrate as in the substrate 10 according to the first embodiment but also a configuration in which the substrate has the cutout 20 on the edge of the substrate as in the substrate 10 according to the second embodiment.

The substrate 10 according to the second embodiment has at least one cutout 20. Note that another cutout may further be formed on the edge of the substrate 10 as required. In the present example, a configuration in which one orientation flat is formed as the cutout 20 is shown.

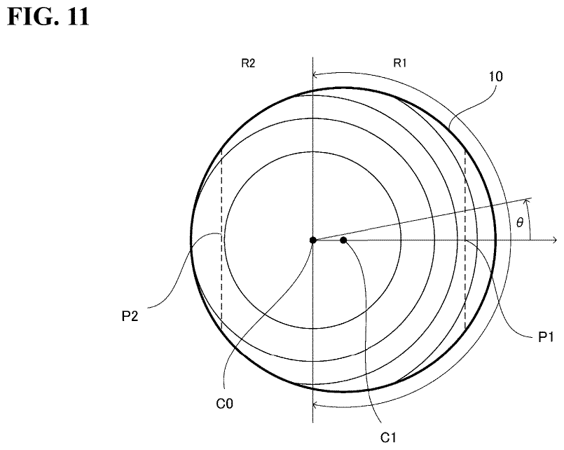

The cutout 20 (orientation flat or notch) is formed to have a shape that is symmetric across a predetermined radial direction of the substrate 10. The position of the cutout 20 in the substrate 10 is defined by the center position (orientation of the radial direction) of the cutout 20. Details on how the position of the cutout 20 is defined (which value is used to represent the position of the cutout 20) are described later with reference to FIG. 11.

The substrate 10 according to the second embodiment is produced by preparing the substrate 10 according to the first embodiment, and forming the cutout 20 (orientation flat or notch) at a predetermined position on an edge of the substrate 10 according to the first embodiment. Known various methods may be used as a method of forming the cutout 20.

As described in the first embodiment, stress at an edge of the substrate 10 can be reduced in the eccentric configuration as compared with the concentric configuration. Consequently, for example, an advantage that cracking of the edge of the substrate 10 during processing of forming the cutout 20 can be suppressed is provided, for example.

In the second embodiment, as the first example (see FIG. 5), a configuration in which the cutout 20 is formed on the substrate center C1 side in the displacing direction is described, and as the second example (see FIG. 9), a configuration in which the cutout 20 is formed on the striation center C0 side in the displacing direction is described.

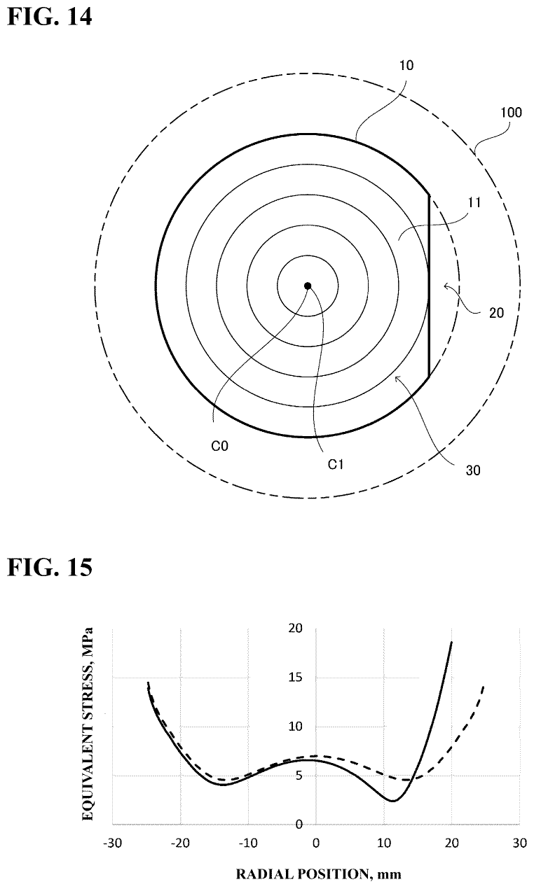

FIG. 14 is a schematic plan view illustrating the substrate 10 according to a second comparative embodiment corresponding to related art. The substrate 10 according to the second comparative embodiment is a substrate obtained by forming the cutout 20 on an edge of the substrate 10 according to the first comparative embodiment (that is, according to the concentric configuration).

The inventor of the present application investigates, through simulation, a difference between a stress distribution in the substrate 10 in which no cutout 20 is formed (the first comparative embodiment and the first embodiment) and a stress distribution in the substrate 10 in which the cutout 20 is formed (the second comparative embodiment and the second embodiment) with respect to each of the concentric configuration and the eccentric configuration. As the cutout 20, an orientation flat having a radial notch width of 5 mm (10% of the diameter of 50 mm of the substrate 10) is formed.

In the eccentric configuration, the cutout 20 on the substrate center C1 side is formed in each of the cases where the displacement amount d is 2.5 mm, 5 mm, and 9 mm, and the cutout 20 on the striation center C0 side is formed in the case in which the displacement amount dis 5 mm. In the concentric configuration, the cutout 20 is formed at a position similar to that of the cutout 20 on the substrate center C1 side in the eccentric configuration.

First, a result of the first example (see FIG. 5) of the second embodiment in which the cutout 20 is formed on the substrate center C1 side is described. FIG. 6 is a graph showing a distribution in the displacing direction of the equivalent stress of the substrate 10 (the first embodiment) with no cutout 20 formed and the equivalent stress of the substrate 10 (the first example of the second embodiment) with the cutout 20 formed on the substrate center C1 side in the eccentric configuration. A result of a case in which the displacement amount d is 5 mm is shown. The stress distribution of the substrate 10 with no cutout 20 formed is indicated by a dashed line, and the stress distribution of the substrate 10 with the cutout 20 formed on the substrate center C1 side is indicated by a sold line. Note that the stress distribution of the substrate 10 with no cutout 20 formed indicated by the dashed line in FIG. 6 is the same as the stress distribution of the substrate 10 of the first embodiment indicated by the solid line in FIG. 2.

A radial position of +5 mm indicates the center C1 of each substrate 10. The substrate 10 with no cutout 20 formed corresponds to a radial position range from −20 mm to +30 mm, and the substrate 10 with the cutout 20 formed on the substrate center C1 side corresponds to a radial position range from −20 mm to +25 mm.

A difference between the stress distribution of the substrate 10 with the cutout 20 formed and the stress distribution of the substrate 10 with no cutout 20 formed is considered to be a change in stress distribution accompanying formation of the cutout 20.

On the side opposite to the cutout 20 with respect to the substrate center C1, little change in stress distribution accompanying formation of the cutout 20 is observed. On the cutout 20 side with respect to the substrate center C1, an increase in stress at the edge is observed accompanying formation of the cutout 20. Incidentally, a tendency of the value of the local minimum of stress to decrease is also observed.

FIG. 15 is a graph showing a distribution in the displacing direction of the equivalent stress of the substrate 10 (the first comparative embodiment) with no cutout 20 formed and the equivalent stress of the substrate 10 (the second comparative embodiment) with the cutout 20 formed in the concentric configuration. The stress distribution of the substrate 10 with no cutout 20 formed is indicated by a dashed line, and the stress distribution of the substrate 10 with the cutout 20 formed is indicated by a solid line. Note that the stress distribution of the substrate 10 with no cutout 20 formed indicated by the dashed line in FIG. 15 is the same as the stress distribution of the substrate 10 of the first comparative embodiment indicated by the solid line in FIG. 13.

A radial position of 0 mm indicates the center C1 of each substrate 10. The substrate 10 with no cutout 20 formed corresponds to a radial position range from −25 mm to +25 mm, and the substrate 10 with the cutout 20 formed corresponds to a radial position range from −25 mm to +20 mm.

Also in the concentric configuration, a difference between the stress distribution of the substrate 10 with the cutout 20 formed and the stress distribution of the substrate 10 with no cutout 20 formed is similar to the difference (that is, the tendency of the change in stress distribution accompanying formation of the cutout 20) described for the eccentric configuration.

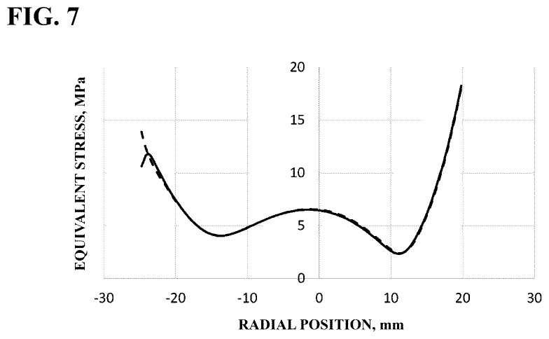

FIG. 7 is a graph showing a distribution in the displacing direction of the equivalent stress (FIG. 15) of the substrate 10 (the second comparative embodiment) with the cutout 20 formed in the concentric configuration and the equivalent stress (FIG. 6) of the substrate 10 (the first example of the second embodiment) with the cutout 20 formed on the substrate center C1 side in the eccentric configuration. The curves of the concentric and eccentric configurations are superimposed in the graph, with the center C1 of the substrate 10 set as a radial position of 0 mm in both configurations. The stress distribution in the concentric configuration is indicated by a dashed line, and the stress distribution in the eccentric configuration is indicated by a solid line.

In the first embodiment, that is, in the eccentric configuration with no cutout 20 formed, a decrease in stress is observed at the edge on each side as compared with the concentric configuration. On the other hand, in the second embodiment, that is, in the eccentric configuration with the cutout 20 formed, a decrease in stress is observed at the edge on the side on which no cutout 20 is formed as compared with the concentric configuration, and an increase in stress to a level approximately equal to that in the concentric configuration is observed accompanying formation of the cutout 20 at the edge on the side on which the cutout 20 is formed.

In this manner, in the eccentric configuration with the cutout 20 formed, the effect of reducing stress as compared with the concentric configuration is not particularly observed at the edge on the side on which the cutout 20 is formed. Provided that, as described above, the effect of reducing stress at an edge is observed in the eccentric configuration before forming the cutout 20. In addition, at the edge on the side on which no cutout 20 is formed, the effect of reducing stress as in the configuration with no cutout 20 formed is observed (maintained) as compared with the concentric configuration.

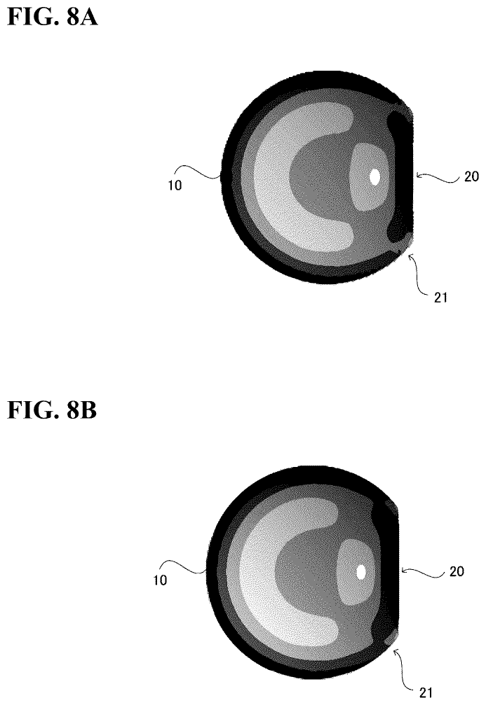

FIG. 8A is a schematic plan view illustrating an in-plane distribution of the equivalent stress of the substrate 10 (the first example of the second embodiment) in the eccentric configuration in which the cutout 20 is formed on the substrate center C1 side. FIG. 8B is a schematic plan view illustrating an in-plane distribution of the equivalent stress of the substrate 10 (the second comparative embodiment) in the concentric configuration with the cutout 20 formed. A region with larger stress is shown darker, and a region with smaller stress is shown lighter.

In the eccentric configuration (the first example of the second embodiment) in which the cutout 20 is formed on the substrate center C1 side as illustrated in FIG. 8A, the stress in the vicinity of a corner 21 formed at an end of the cutout 20 (orientation flat) is reduced as compared with that in the concentric configuration (the second comparative embodiment) in which the cutout 20 is formed as illustrated in FIG. 8B.

Summarizing the (one-dimensional) stress distribution in the displacing direction shown in FIG. 7 and the (two-dimensional) in-plane stress distribution illustrated in FIG. 8A, the following tendencies are observed with respect to the equivalent stress in the vicinity of the cutout 20 in the eccentric configuration (the first example of the second embodiment) in which the cutout 20 is formed on the substrate center C1 side.

An increase in stress to a level approximately equal to that in the concentric configuration is observed accompanying formation of the cutout 20 at the edge (that is, the center position in the length direction of the orientation flat) on the side on which the cutout 20 is formed in the displacing direction. However, a decrease in stress in the vicinity of the corner 21 formed at the end of the cutout 20 (orientation flat) is observed as compared with the concentric configuration.

Next, a result of the second example of the second embodiment (see FIG. 9) in which the cutout 20 is formed on the striation center C0 side is described. FIG. 10 is a graph showing a distribution in the displacing direction of the equivalent stress of the substrate 10 (the first embodiment) with no cutout 20 formed and the equivalent stress of the substrate 10 (the second example of the second embodiment) with the cutout 20 formed on the striation center C0 side in the eccentric configuration. A result in a case in which the displacement amount d is 5 mm is shown. The stress distribution of the substrate 10 with no cutout 20 formed is indicated by a dashed line, and the stress distribution of the substrate 10 with the cutout 20 formed on the striation center C0 side is indicated by a solid line. Note that the stress distribution of the substrate 10 with no cutout 20 formed indicated by the dashed line in FIG. 10 is the same as the stress distribution of the substrate 10 of the first embodiment indicated by the solid line in FIG. 2.

A radial position of +5 mm indicates the center C1 of each substrate 10. The substrate 10 with no cutout 20 formed corresponds to a radial position range from −20 mm to +30 mm, and the substrate 10 with the cutout 20 formed on the striation center C0 side corresponds to a radial position range from −15 mm to +30 mm.

Also in the eccentric configuration in which the cutout 20 is formed on the striation center C0 side, a difference (that is, the tendency of a change in stress distribution accompanying formation of the cutout 20) between the stress distribution of the substrate 10 with the cutout 20 formed and the stress distribution of the substrate 10 with no cutout 20 formed is similar to the difference described for the eccentric configuration in which the cutout 20 is formed on the substrate center C1 side. That is, an increase in equivalent stress at the edge portion (and a decrease in local minimum value) is observed on the side on which the cutout 20 is formed with respect to the substrate center C1.

Note that also in the eccentric configuration in which the cutout 20 is formed on the striation center C0 side, similar to the eccentric configuration in which the cutout 20 is formed on the substrate center C1 side (see FIG. 7), a decrease in stress is observed at the edge on the side on which no cutout 20 is formed as compared with the concentric configuration, and an increase in stress to a level approximately equal to that in the concentric configuration accompanying formation of the cutout 20 is observed at the edge on the side on which the cutout 20 is formed.

FIG. 11 is a schematic plan view illustrating a distribution of the deflection amount in the substrate 10 in the eccentric configuration. Regions in which the deflection amount is equal in the substrate 10 are distributed concentrically around the striation center C0. In addition, the deflection amount increases as the distance from the striation center C0 increases. Positions at which the deflection amount is equal are indicated by concentric lines.

An azimuth angle θ centered on the striation center C0 is defined, with the direction from the striation center C0 toward the substrate center C1 (that is, the positive side in the displacing direction) set as an azimuth angle of 0°. The region (area on the right-hand side of FIG. 11 with respect to the striation center C0) within an azimuth angle θ range of −90° or more and 90° or less is a region R1. The region outside the region R1, that is, the region (area on the left-hand side of FIG. 11 with respect to the striation center C0) within an azimuth angle θ range of more than −180° and less than −90° and more than 90° and 180° or less is a region R2.

The position of the cutout 20 is defined by the azimuth angle θ indicating the center position of the cutout 20. The first example of the second embodiment in which the cutout 20 is formed on the substrate center C1 side is an example of a configuration in which the cutout 20 is located at a position P1 at which the azimuth angle θ is 0° and in which the cutout 20 is provided on an edge of the principal surface 11 within an azimuth angle θ range of −90° or more and 90° or less (region R1). The second example of the second embodiment in which the cutout 20 is formed on the striation center C0 side is an example of a configuration in which the cutout 20 is located at a position P2 at which the azimuth angle θ is 180° and in which the cutout 20 is provided within an azimuth angle θ range of more than −180° and less than −90° and more than 90° and 180° or less (region R2).

The deflection amount at the edge of the substrate 10 in the region R1 is larger than the deflection amount at the edge of the substrate 10 in the region R2. Accordingly, in the configuration in which the cutout 20 is formed in the region R1, as compared with the configuration in which the cutout 20 is formed in the region R2, a portion of the substrate 10 having a larger deflection amount is cut off accompanying formation of the cutout 20. Consequently, in the configuration in which the cutout 20 is formed in the region R1, an average deflection amount in the substrate 10 with the cutout 20 formed can be reduced as compared with the configuration in which the cutout 20 is formed in the region R2.

As the azimuth angle θ approaches 0°, the edge of the substrate 10 is farther from the striation center C0, and the deflection amount at the edge of the substrate 10 thus increases. From the viewpoint of decreasing the average deflection amount of the substrate 10 with formation of the cutout 20, it is more preferable that the cutout 20 be formed in a range in which the azimuth angle θ is close to 0°.

From such a viewpoint, (at least one) cutout 20 is formed preferably within an azimuth angle θ range of −90° or more and 90° or less, more preferably within an azimuth angle θ range of −60° or more and 60° or less, still more preferably within an azimuth angle θ range of −45° or more and 45° or less, and especially preferably within an azimuth angle θ range of −30° or more and 30° or less.

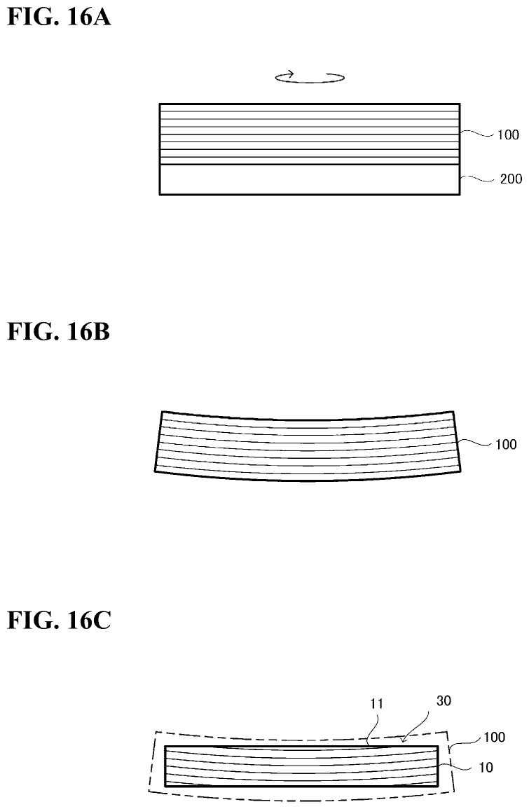

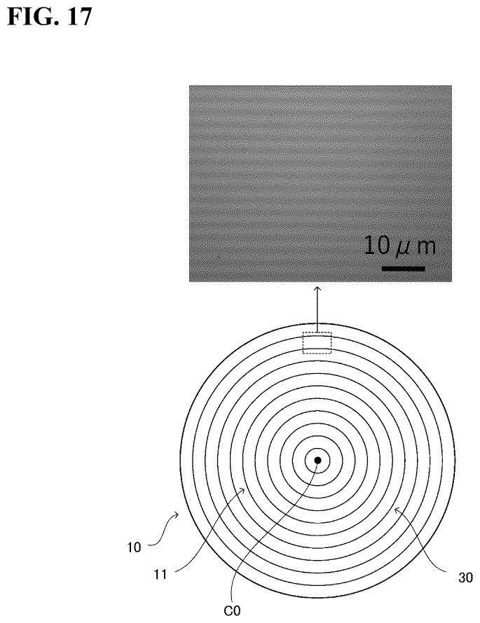

A method of producing the base material 100 and the substrate 10 is described. FIG. 16A to FIG. 16C are schematic cross-sectional views schematically illustrating the method of producing the base material 100 and the substrate 10. FIG. 16A illustrates a step of growing the base material 100, that is, a step of growing a gallium nitride single crystal forming the base material 100. The base material 100 is grown by, for example, a void-assisted separation (VAS) method.

A circular seed substrate 200 having a diameter larger than that of the substrate 10 obtained from the base material 100 is prepared. The base material 100 is formed by growing a gallium nitride single crystal in the c-axis direction on the seed substrate 200, while causing at least self-rotation of the seed substrate 200. The seed substrate 200 is rotated about the center of the circular seed substrate 200, that is, around the center of the circular base material 100. Incidentally, the base material 100 may be grown while undergoing revolution in addition to self-rotation as required. Because gallium nitride growth conditions periodically vary with self-rotation and the like, a structure in which a physical property (for example, an impurity concentration) periodically changes in the thickness direction of growing gallium nitride is formed.

As described later, variation in impurity concentration, that is, a structure in which a region with a high impurity concentration and a region with a low impurity concentration are alternately arranged is specifically detected with a fluorescence microscope as striations. In order to clearly detect the striations, the concentration of the region with a high impurity concentration is preferably 1×10¹⁷/cm³ or more, for example. An impurity may be intentionally added, or may be unavoidably incorporated. Examples of the impurity include silicon (Si) and germanium (Ge) intentionally added during growth in an HVPE method, and include oxygen (O) unavoidably incorporated during growth in an OVPE method.

FIG. 16B illustrates the base material 100 separated from the seed substrate 200. In the separated base material 100, a curvature is formed on the c-plane of the gallium nitride single crystal due to tensile stress introduced during growth of gallium nitride. By using a growing method with which the distribution of initial nuclei becomes uniform in a plane, such as the VAS method, the c-plane in the base material 100 is curved so as to have a uniform radius of curvature in the plane, that is, in a spherical shape.

FIG. 16C illustrates a step of cutting out (removing an unnecessary portion in order to obtain the substrate 10) the substrate 10 from the base material 100. As a processing method for cutting out the substrate 10 from the base material 100, for example, grinding processing, ultrasonic machining, electrical discharge machining, laser machining, and the like are used. Note that one sheet of the substrate 10 may be obtained from the base material 100, or multiple sheets of the substrates 10 may be obtained by slicing a member cut out from the base material 100, as required.

The substrate 10 obtained from the base material 100 has a plate shape, and the principal surface 11 is processed to have a planner surface. The substrate 10 is obtained such that the principal surface 11 is substantially perpendicular to the self-rotation axis direction during growth of the gallium nitride single crystal. That is, the substrate 10 is a c-plane substrate, and the direction normal to the principal surface 11 is substantially parallel (the degree of the deviation between the direction normal to the principal surface 11 and the c-axis direction is, for example, 1° or less) to the c-axis direction of the gallium nitride single crystal. In the base material 100, end faces of respective c-planes that are curved in a spherical shape and stacked are exposed concentrically within the principal surface 11 of the substrate 10. Accordingly, the periodic structure formed in the thickness direction of the base material 100 is exposed concentrically in the principal surface 11.

In this manner, the striations 30, which is a structure having a physical property (for example, an impurity concentration) concentrically changing in the principal surface 11 is formed. The center C0 of the concentric circles of the striations 30 indicates the center of self-rotation during growth of gallium nitride, and is also located at the center of the circular base material 100.

In the first comparative embodiment (and the second comparative embodiment) (that is, in related art), the substrate 10 is obtained by cutting out the substrate 10 so that the center C1 of the substrate 10 and the center C0 of the striations 30 coincide (see FIG. 12).

In the first embodiment (and the second embodiment), the substrate 10 is obtained by cutting out the substrate 10 (that is, by processing the base material 100 so that the substrate center C1 is located at the position different from the center of self-rotation during growth of the gallium nitride single crystal) so that the center C1 of the substrate 10 is displaced by a predetermined displacement amount d from the center C0 of the striations 30 (see FIG. 1).

In order to form the striations 30 with a concentric structure, the gallium nitride single crystal is preferably grown so that a spherical c-plane with suppressed distortion is obtained. In order to achieve such growth, it is preferable to enhance uniformity of growth conditions, specifically, to perform growth in the following manner, for example.

It is preferable that the seed substrate 200 and the base material 100 be circular, centers of the circular seed substrate 200 and base material 100 are set to be the center of self-rotation during growth of gallium nitride. In addition, a growing method with which initial nuclei are uniformly distributed in a plane of the seed substrate 200 is preferably used. Therefore, a growth method such as epitaxial lateral overgrowth (ELO), in which initial nuclei are non-uniformly generated in a plane by using a mask pattern, is not preferable.

The fact that the striations 30 are formed so as to be concentric indicates that a gallium nitride material having isotropic characteristics in the circumferential direction with respect to the center C0 of the striations 30 is obtained. Therefore, when the cutout 20 is not provided in the eccentric configuration, the direction (orientation) in which the center C1 of the substrate 10 is displaced from the center C0 of the striations 30 may be any direction (orientation).

When the cutout 20 is provided, the direction (orientation) in which the center C1 of the substrate 10 is displaced is preferably determined through back calculation based on the position of the cutout 20 so that the cutout 20 is located on an edge of the principal surface 11 within the range in which the azimuth angle centered on the center C0 of the striations 30 is −90° or more and 90° or less (preferably −60° or more and 60° or less, more preferably −45° or more and 45° or less, and still more preferably −30° or more and 30° or less), with the direction from the center C0 of the striations 30 toward the center C1 of the substrate 10 set as an azimuth angle of 0°. That is, when the cutout 20 is provided, the substrate 10 (the substrate 10 in a state in which the cutout 20 is not yet formed) of the first embodiment is prepared after the displacing direction is preliminarily determined through back calculation based on the position of the cutout 20. Note that the position at which the cutout 20 is provided may be appropriately selected according to design, specifically, is determined according to customer specification requirements for the substrate 10, for example, and thus cannot be determined to be a single crystal orientation.

FIG. 17 is a fluorescence micrograph showing an example of the striations 30. The striations 30 are observed as bright and dark stripes when the principal surface 11 of the substrate 10 is observed with a fluorescence microscope. The contrast observed with the fluorescence microscope is specifically caused by a difference in the concentration of impurities contained in gallium nitride.

As shown in FIG. 17, when the diameter of concentric circles in an observation area is excessively large (as compared to the size of the observation area), the striations 30 are observed not as concentric circles but as substantially parallel stripes (because the observation area is small in a single field of view). In such a case, by moving the microscope stage to trace the same line of the striations 30, it can be confirmed that the line is circular, and the center of the circle, that is, the striation center C0 can be detected.

Incidentally, the striation center C0 may be detected by another method. For example, multiple positions on the principal surface 11 may be observed with a fluorescence microscope, and the striation center C0 may be detected as a position at which directions (that is, the diametric directions of concentric circles) orthogonal to stripes intersect with each other at multiple points in a stripe pattern. As the multiple points observed, positions at which directions orthogonal to stripes are not parallel to each other (intersect with each other) are selected. In addition, the striation center C0 may be detected by directly observing a central area of concentric circles, for example.

The substrate center C1 is detected on the basis of the shape of the circular substrate 10. In the substrate 10 in the eccentric configuration, the substrate center C1 is located at a position displaced from the striation center C0 (see FIG. 1).

### Examples

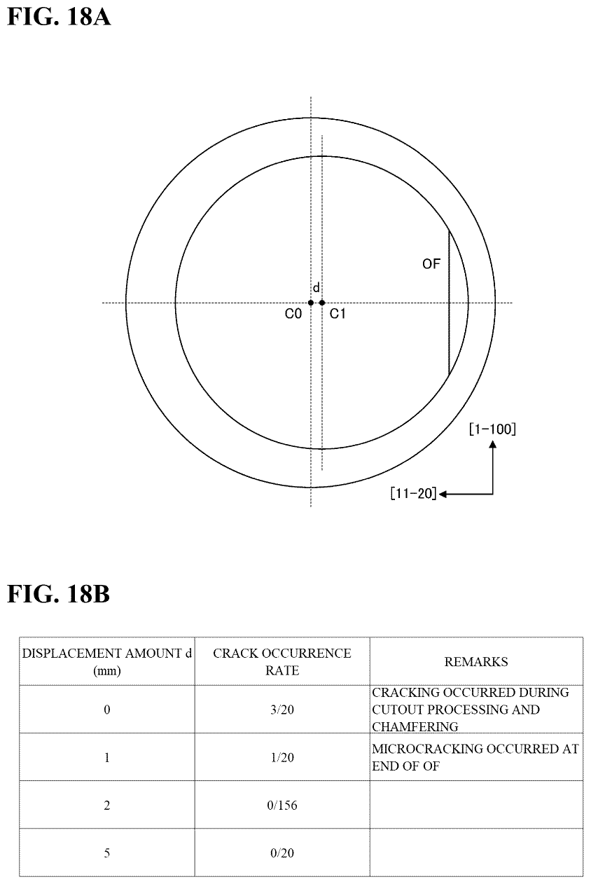

An experiment in which an orientation flat (OF) was formed on each of GaN substrates with different displacement amounts d, and likelihood of occurrence of cracking was investigated is described below. FIG. 18A is a schematic plan view illustrating a GaN substrate in this experiment.

A c-plane GaN substrate was produced by a VAS method using a sapphire substrate with a diameter of 76.2 mm. The diameter of an as-grown substrate (that is, a base material) was about 70 mm. The base material was processed to obtain a substrate with a diameter of 50 mm and a thickness of 400 μm, and an OF was formed. The OF was formed on the a-plane. The length of the OF was set to 16 mm.

Four types of substrates were produced, with the displacement amount d changed to 0 mm, 1 mm, 2 mm, and 5 mm, respectively. The displacing direction was set so as to achieve an eccentric configuration in which the substrate center C1 is located on the OF side relative to the striation center (the center of the base material) C0.

After crystal growth, a circular cutout was formed with the displacement amount set to a predetermined amount to produce a circular substrate before OF formation. The circular substrate before OF formation was subjected to front and rear surface grinding, followed by chamfering and OF processing to produce a substrate with an OF formed. Note that the substrate with an OF formed was then subjected to mirror polishing to produce a finished substrate.

The circular cutout processing was carried out with a horizontal grinding device (horizontal cutout device) using an electrodeposited diamond core drill. The front and rear surface grinding was performed with the same device using a vitrified bond wheel. The chamfering and OF processing were performed with using a chamfering machine using a resin bond wheel.

FIG. 18B is a table summarizing results of the experiment. When the displacement amount d was 0 mm (that is, in the concentric configuration), cracking occurred in 3 substrates out of 20 substrates (crack occurrence rate was 3/20). Cracking occurred during the cutout processing and chamfering. When the displacement amount d was 1 mm (2% of the substrate diameter), cracking occurred in 1 substrate out of 20 substrates (crack occurrence rate was 1/20). Microcracking occurred at an end of the OF. When the displacement amount d was 2 mm (4% of the substrate diameter), cracking did not occur in 156 substrates. When the displacement amount d was 5 mm (10% of the substrate diameter), cracking did not occur in 20 substrates.

In the (eccentric) configuration in which the displacement amount d was not 0 (specifically, in this experiment, when the displacement amount was 2% or more of the substrate diameter), the crack occurrence rate decreased as compared with the (concentric) configuration in which the displacement amount d was 0. In addition, while occurrence of cracking was observed in the case in which the displacement amount d was 1 mm (2% of the substrate diameter), occurrence of cracking was not observed in the case in which the displacement amount d was 2 mm (4% of the substrate diameter) and in the case in which the displacement amount was 5 mm (10% of the substrate diameter) (that is, in the cases in which the displacement amounts were 4% or more of the substrate diameter).

### PREFERRED ASPECTS OF PRESENT DISCLOSURE

Preferred aspects of the present disclosure are supplementally noted below.

### Supplementary Note 1

A gallium nitride single-crystal substrate including a single crystal of gallium nitride, the substrate being a circular substrate having concentric striations (preferably having a radius of 25 mm or more) observed as bright and dark stripes when a principal surface of the substrate is observed with a fluorescence microscope, in which
a substrate center, which is a center of the circular substrate, is located at a position displaced from a striation center, which is a center of the concentric striations.

### Supplementary Note 2

The gallium nitride single-crystal substrate according to Supplementary Note 1, in which a distance between the substrate center and the striation center is 0.5% or more (preferably 0.9% or more, more preferably 1.8% or more, still more preferably 2.7% or more, yet still more preferably 3.6% or more, and especially preferably 4.5% or more) of the diameter of the substrate.

### Supplementary Note 3

The gallium nitride single-crystal substrate according to Supplementary Note 1, in which a distance between the substrate center and the striation center is less than 25.7% (preferably 23.0% or less, more preferably 20.4% or less, still more preferably 17.8% or less, yet still more preferably 15.1% or less, and especially preferably 12.5% or less) of the diameter of the substrate.

### Supplementary Note 4

The gallium nitride single-crystal substrate according to Supplementary Note 1, further including a cutout indicating a crystal orientation of the gallium nitride.

### Supplementary Note 5

The gallium nitride single-crystal substrate according to Supplementary Note 4, in which when a direction from the striation center toward the substrate center is set as an azimuth angle of 0°, the cutout is provided on an edge of the principal surface within an azimuth angle range of −90° or more and 90° or less (preferably −60° or more and 60° or less, more preferably −45° or more and 45° or less, and still more preferably −30° or more and 30° or less) about the striation center.

### Supplementary Note 6

A method of producing a gallium nitride single-crystal substrate, the method including:
forming a base material by growing a gallium nitride single crystal on a circular seed substrate while causing at least self-rotation of the seed substrate, in which the seed substrate has a diameter larger than the diameter of a circular gallium nitride single-crystal substrate to be obtained; and
obtaining the gallium nitride single-crystal substrate by processing the base material in such a manner that a substrate center is located at a position different from a center of the self-rotation during growth of the gallium nitride single crystal, in which the substrate center is a center of the circular gallium nitride single-crystal substrate.

### DESCRIPTION OF REFERENCE NUMERALS

10: Gallium nitride single-crystal substrate
11: Principal surface
12: Cutout
21: Corner
30: Striation
100: Base material
200: Seed substrate

What is claimed is:

1. A gallium nitride single-crystal substrate comprising a single crystal of gallium nitride, the substrate being a circular substrate having concentric striations observed as bright and dark stripes when a principal surface of the substrate is observed with a fluorescence microscope, wherein
a substrate center is located at a position displaced from a striation center, the substrate center being a center of the circular substrate, and the striation center being a center of the concentric striations.

2. The gallium nitride single-crystal substrate according to claim 1, wherein
a distance between the substrate center and the striation center is 0.5% or more of the diameter of the substrate.

3. The gallium nitride single-crystal substrate according to claim 1, wherein
a distance between the substrate center and the striation center is less than 25.7% of the diameter of the substrate.

4. The gallium nitride single-crystal substrate according to claim 1, further comprising a cutout indicating a crystal orientation of the gallium nitride.

5. The gallium nitride single-crystal substrate according to claim 4, wherein
when a direction from the striation center toward the substrate center is set as an azimuth angle of 0°, the cutout is provided on an edge of the principal surface within an azimuth angle range of −90° or more and 90° or less about the striation center.

6. A method of producing a gallium nitride single-crystal substrate, the method comprising:
forming a base material by growing a gallium nitride single crystal on a circular seed substrate while causing at least self-rotation of the seed substrate, wherein the seed substrate has a diameter larger than the diameter of a circular gallium nitride single-crystal substrate to be obtained; and
obtaining the gallium nitride single-crystal substrate by processing the base material in such a manner that a substrate center is located at a position different from a center of the self-rotation during growth of the gallium nitride single crystal, wherein the substrate center is a center of the circular gallium nitride single-crystal substrate.
